(19) United States
(12) Patent Application Publication
(10) Pub. No.: US 2002/0137339 A1
(43) Pub. Date: Sep. 26, 2002

(54) Semiconductor device and manufacturing method thereof

(76) Inventor: Hideki Takeuchi, Tokyo (JP)

Correspondence Address: CONNOLLY BOVE LODGE & HUTZ LLP, SUITE 800, 1990 M STREET NW, WASHINGTON, DC, 20036-3425, US

(21) Appl. No.: 10/146,951

(22) Filed: May 17, 2002

Related U.S. Application Data
(62) Division of application No. 08/816,144, filed on Mar. 12, 1997.

(30) Foreign Application Priority Data
Mar. 26, 1996 (JP) 08-096097

(51) Int. Cl. H01L 21/44; H01L 21/4763; H01L 21/31; H01L 21/469

(52) U.S. Cl. 438/688; 438/763; 438/624

(57) ABSTRACT

A semiconductor device and manufacturing method thereof in which upon patterning of an Al strain metal wiring, an occurrence of side etch due to an emission of oxygen from an interlayer insulating film of an underlayer is prevented. A silicon nitride film or the like containing no oxygen is formed on the surface portion of an under BPSG film. A TiW film or the like serving as a barrier metal and an Al strain metal film are formed on the silicon nitride film. A side wall protecting film by carbon generated from an organic substance photoresist is preferably formed, thereby preventing the side etch of the Al strain metal film.

### BACKGROUND OF THE INVENTION

1. Field of the Invention

The invention relates to a semiconductor device and manufacturing method thereof and, more particularly, to a semiconductor device and manufacturing method thereof in which anisotropic etching is performed by using a photoresist of an organic substance as an etching mask in order to work a barrier metal layer and an aluminum strain (aluminum or aluminum alloy) metal film formed on an insulating film into a wiring shape.

2. Description of the Related Art

Hitherto, in a semiconductor device, an aluminum strain metal wiring made of aluminum as a main component has widely been used. A titanium tungsten film having an excellent stairway coating performance is used as a barrier metal layer to suppress a reaction between a silicon substrate and an aluminum strain metal.

However, in association with the realization of a fine wiring pattern in recent years, new problems occur when the semiconductor device as mentioned above is manufactured. Namely, when the titanium tungsten film as a barrier metal layer and the aluminum strain metal film formed thereon are patterned in a wiring shape by anisotropic etching, so-called side etch occurs in a side wall portion near a boundary between the titanium tungsten film and the aluminum strain metal film and the wiring shape becomes defective, as a result, such problems occur that resistance of the wiring is increased and disconnection is caused.

A mechanism by which the side etch occurs will now be described in detail.

In the manufacturing of the conventional semiconductor device, a BPSG (boro-phospho silicate glass) film which is generally used as an interlayer insulating film for planarizing (planation or flattening) purpose is formed on a silicon semiconductor substrate, a titanium tungsten (TiW) film is formed as a barrier metal layer on the BPSG film, and an aluminum strain metal film, for example, an Al—Si—Cu film is further formed on the TiW film.

After that, in order to work the aluminum strain metal film and the titanium tungsten film into a wiring shape, anisotropic etching is executed by using a photoresist of an organic substance as an etching mask. In this instance, carbon is generated from the photoresist of the organic substance and is deposited onto the side wall of the aluminum strain metal film, thereby forming a side wall protecting film. Ordinarily, the side etch of the aluminum strain metal film is blocked by the side wall protecting film. Namely, although the aluminum strain metal film reacts with, for example, chlorine radicals which are generated in a plasma of an etching gas, since the side wall protecting film prevents a contact between the chlorine radicals and the aluminum strain metal film, the side wall of the aluminum strain metal film under the photoresist is not etched, so that a wiring pattern of a vertical shape can be derived.

However, if a portion of a dense wiring pattern and a portion of a coarse wiring pattern exist, so-called micro-loading effect occurs in which an etching speed in the portion of the coarse wiring pattern is larger than that in the portion of the dense wiring pattern. Due to the micro-loading effect, there is a case where when the aluminum strain metal film is etched in the portion where the wiring pattern is dense, the etching of the titanium tungsten film is finished in the portion where the wiring pattern is dense. If the etching is further continued in such a case, oxygen is emitted from an underlayer of the BPSG film exposed in the portion of the coarse wiring pattern and this oxygen reacts with the carbon generated from the photoresist of the organic substance and forms carbon monoxide or carbon dioxide. Therefore, the formation of the side wall protecting film is insufficient. When the etching is further continued in such a state, side surfaces of the aluminum strain metal film and titanium tungsten film under the photoresist are also etched. Particularly, the side etch occurs in the side wall portion near the boundaries where the formation of the side wall protecting film is insufficient.

Especially, according to etching conditions of the aluminum strain metal, an etching time of titanium tungsten (TiW) is relatively long because its etching rate is lower than that of titanium (Ti) or titanium nitride (TiN). Therefore, in case of using the titanium tungsten film as a barrier metal, the foregoing phenomenon remarkably appears as compared with the case of using the titanium film or titanium nitride film.

To solve such problems, dry etching methods in which compositions of the etching gas were improved are disclosed in JP-A-5-234961 and JP-A-7-66176. Further, in JP-A-7-263426, a dry etching method of a laminate wiring is disclosed whereby a metal layer of a high melting point is etched while forming a side wall protecting film on a side wall of an etched pattern and subsequently an aluminum strain metal layer is etched. However, only the improvement of the etching method is disclosed in those documents and nothing is disclosed with respect to preventing the side etch by improving a structure of a semiconductor device itself.

In JP-A-3-104230, a manufacturing method of a semiconductor device is disclosed whereby a plated wiring layer of a predetermined thickness is first formed at a high current density and is plated wiring layer is subsequently formed thereon at a low current density for the purpose of preventing a plating from being deposited to portions other than a desired portion when the wiring layer is plated. However, this document does not disclose preventing the side etch.

### SUMMARY OF THE INVENTION

It is, therefore, an object of the invention to provide semiconductor device and manufacturing method thereof in which even in case of performing an anisotropic etching by using a photoresist of an organic substance as an etching mask in order to work a barrier metal layer and an aluminum strain metal film formed on an insulating film, no side etch occurs in the side wall portion near an interface between the barrier metal layer and the aluminum strain metal film.

To accomplish the above object, a semiconductor device according to the first aspect of the invention comprises: a semiconductor substrate; a first insulating film formed in at least a part of the semiconductor substrate and including oxygen as a component; a second insulating film formed on the first insulating film and substantially including no oxygen; a first conductive layer formed selectively on the second insulating film; and a second conductive layer formed on the first conductive layer.

A manufacturing method of the semiconductor device according to the first aspect of the invention comprises the steps of: forming a first insulating film including oxygen as a component on at least a part of a semiconductor substrate; forming a second insulating film substantially including no oxygen as a component on the first insulating film; forming a first conductive layer on the second insulating film; forming a second conductive layer on the first conductive layer; and patterning the first and second conductive layers by anisotropic etching using a resist of an organic substance as an etching mask.

According to the first aspect of the invention, since the second insulating film which does not contain oxygen is formed on the first insulating film containing oxygen, even if the etching of the first conductive layer is finished in the portion of a coarse wiring pattern, the first insulating film is not exposed and oxygen is not emitted. Therefore, the formation of the side wall protecting film of the conductive layer due to carbon generated from the photoresist of the organic substance is not obstructed and the etching progresses in a state in which the side surfaces of the conductive layer under the photoresist are preferably covered by the side wall protecting film, so that the generation of the side etch as in the conventional technique can be prevented.

Even when a film having an oxygen concentration smaller than that of the first insulating film is used as a second insulating film, the generation of the side etch can be also reduced.

Further, a semiconductor device according to the second aspect of the invention comprises: a semiconductor substrate; an insulating film formed on at least a part of the semiconductor substrate and having an oxygen concentration which decreases in accordance with a distance from the surface of the semiconductor substrate; a first conductive layer selectively formed on the insulating film; and a second conductive layer formed on the first conductive layer.

A manufacturing method of the semiconductor device according to the second aspect of the invention comprises the steps of: forming an insulating film on at least a part of the semiconductor substrate in a manner such that an oxygen concentration of the insulating film decreases in accordance with a distance from the surface of the semiconductor substrate; forming a first conductive layer on the insulating film; forming a second conductive layer on the first conductive layer; and patterning the first and second conductive layers by anisotropic etching using a resist of an organic substance as an etching mask.

By the second aspect of the invention as well, the generation of the side etch can be similarly reduced.

### BRIEF DESCRIPTION OF THE DRAWINGS

FIGS. 1A to 1C are cross sectional views showing a semiconductor device and manufacturing method thereof according to the first embodiment of the invention in accordance with the order of processing steps; and

FIGS. 2A to 2C are cross sectional views showing a semiconductor device and manufacturing method thereof according to the second embodiment of the invention in accordance with the order of processing steps.

### DESCRIPTION OF THE PREFERRED EMBODIMENTS

A semiconductor device and manufacturing method thereof according to the first embodiment of the invention will now be described hereinbelow with reference to the drawings.

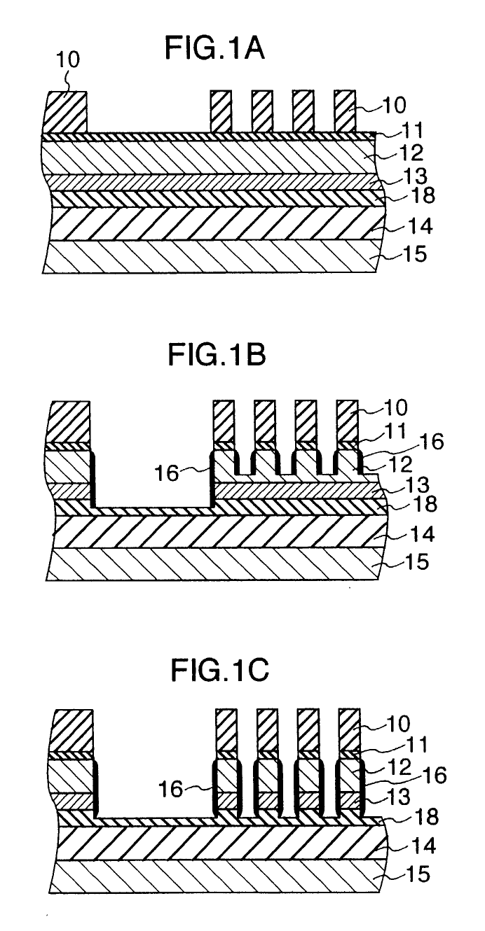

First, as shown in FIG. 1A, a BPSG film having a film thickness of 0.1 to 2.0 μm, more preferably, 400 to 600 nm is formed as a first insulating film 14 onto a silicon semiconductor substrate 15. A plasma silicon nitride (p-SiN) film having a film thickness of 10 to 200 nm, more preferably, 100 nm is formed as a second insulating film 18 on the first insulating film 14. The formation of the plasma silicon nitride film is executed, for example, under conditions of an RF power of 3 kW while supplying an SiH₄ gas at a gas flow rate of 750 ccm and an NH₃ gas at a gas flow rate of 6 l/min and at a temperature of 350° C.

A titanium tungsten (TiW) film having a film thickness of 50 to 200 nm is formed as a barrier metal layer (first conductive layer) 13 by sputtering. A composition ratio of the TiW film may be set to, for example, Ti:W=10%:90%. Further, an aluminum strain metal film having a film thickness of 0.3 to 1.0 μm is formed as a wiring layer (second conductive layer) 12 on the barrier metal layer 13 by sputtering. A composition ratio of the aluminum strain metal film may be set to, for example, Al—Si (0 to 1%)—Cu (0 to 2%).

After that, a reflection preventing film 11 is formed on the aluminum strain metal film by sputtering. The reflection preventing film 11 can be made of amorphous silicon, titanium, or titanium nitride having a film thickness of 10 to 30 nm. Finally a photoresist 10 of an organic substance having a film thickness of 0.5 to 2.5 μm is formed on the reflection preventing film 11 and is patterned to a desired wiring pattern as shown in FIG. 1A.

As shown in FIG. 1B, for example, etching is subsequently executed by using an ECR (electron cyclotron resonance) plasma etcher. As a first step, the reflection preventing film 11 and the aluminum strain metal film as a wiring layer 12 are mainly etched under conditions of a pressure of 5 to 20 mTorr and an anode current of 100 to 400 mA and an RF power 30 to 100 W while supplying a BCl₃ gas at a gas flow rate of 20 to 50 ccm and a Cl₂ gas at a gas flow rate of 20 to 100 ccm. Subsequently, as a second step, the titanium tungsten film as a barrier metal layer 13 is mainly etched under conditions of a pressure of 5 to 20 mTorr and an anode current of 100 to 400 mA and an RF power of 30 to 100 W while supplying a BCl₃ gas at a gas flow rate of 10 to 60 ccm and an SF₆ gas at a gas flow rate of 10 to 100 ccm.

Since an etching rate of the plasma silicon nitride film as a second insulating film 18 locating under the barrier metal layer 13 is very small, when the etching is further progressed from the state shown in FIG. 1B, the etching of the wiring layer 12 and barrier metal layer 13 is completed before the BPSG film as a first insulating film 14 is etched as shown in FIG. 1C.

According to the foregoing manufacturing method, although the BPSG film which is used as a first insulating film 14 contains oxygen, the plasma silicon nitride film which does not contain oxygen is formed as a second insulating film 18 on the first insulating film 14. Therefore, even if the etching of the barrier metal layer 13 is finished in the portion where the wiring pattern is coarse, the PBSG film is not exposed and oxygen is not emitted. Thus, the formation of the side wall protecting film 16 due to carbon generated from the organic substance photoresist 10 is not obstructed but the etching progresses in a state in which the side surfaces of the wiring layer 12 under the photoresist 10 are preferably covered by side protecting film 16 as shown in FIG. 1C, the occurrence of the side etches as in the conventional technique can be prevented.

As a second insulating film 18, in place of the foregoing plasma silicon nitride film, it is possible to use any one of a teflon film, an aluminum nitride film, a diamond film, a silicon film of a high resistance which contains no impurity, and the like. The teflon film mentioned here is defined as a general denomination of a fluoride substance polymer film and includes a tetrafluoroethylene polymer film, a tetrafluoroethylene-hexafluoropropylene polymer film, a tetrafluoro copolymer film, a difluorovinylidene polymer film, a monofluorovinyl polymer film, or the like. In case of using the teflon film, for example, a film having a thickness of 100 to 500 Å is formed under conditions of a pressure of 8 mTorr and an anode current of 300 mA and an RF power of 100 W while supplying a C₄F₈ gas at a gas flow rate of 20 ccm by the ECR etcher. Although a side etch preventing effect slightly deteriorates as compared with those of the above films, a film of a mixture (p-SiON), of plasma silicon oxide and plasma silicon nitride having a low oxygen concentration can be also used. In this case, for example, a film having a thickness of 100 nm is formed under a condition of an RF power of 3 kW while supplying an SiH₄ gas at a gas flow rate of 500 ccm, an O₂ gas at a gas flow rate of 1 to 5 l/min, and an NH₃ gas at a gas flow rate of 5 l/min and a temperature of 350 to 400° C.

As a barrier metal layer 13, in place of the above titanium tungsten (TiW) film, it is also possible to use any one of a laminate film of titanium nitride and titanium (TiN/Ti), a tungsten nitride (WN) film, an alloy film of tungsten and silicon (WSiₓ), and the like. In case of using the laminate film of titanium nitride and titanium, for example, a thickness of titanium nitride film is set to 50 to 200 nm and a thickness of titanium film is set to 20 to 100 nm.

Further, as a first insulating film 14, in place of the foregoing BPSG film, any one of a PSG (phospho-silicate glass) film, a BSG (boro-silicate glass), a plasma silicon oxide (p-SiO) film, and the like can be used. In case of using the plasma silicon oxide film, for example, a film having a thickness of 300 to 900 nm is formed under a condition of an RF power of 3 kW while supplying an SiH₄ gas at a gas flow rate of 500 ccm and an O₂ gas at a gas flow rate of 1 to 5 l/min and a temperature of 350 to 400° C.

A semiconductor device and manufacturing method thereof according to the second embodiment of the invention will now be described with reference to the drawings. The second embodiment differs from the first embodiment with respect to a point that the first and second insulating films in the first embodiment are replaced by one insulating film in which an oxygen concentration varies depending on a height from the semiconductor substrate 15.

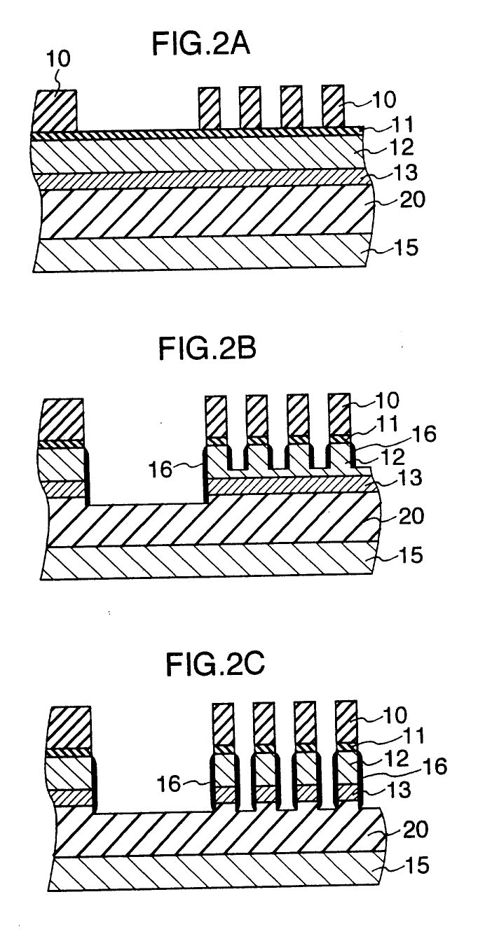

First as shown in FIG. 2A, a film made of a mixture of plasma silicon oxide and plasma silicon nitride (p-SiON) having a film thickness of 0.1 to 2.0 μm is formed as an insulating film 20 on the silicon semiconductor substrate 15 in such a manner that an oxygen concentration at a portion of the insulating film 20 decreases as the position approaches an upper portion. The formation of the film made of the mixture of plasma silicon oxide and plasma silicon nitride is executed by a method whereby, for example, a temperature is set to 350 to 400° C., an RF power is set to 3 kW, a gas flow rate of SiH₄ is fixed to 500 ccm, a gas flow rate of O₂ is changed from 5 lm/min to 1 l/min, and a gas flow rate of NH₃ is changed from 1 l/min to 5 l/min.

In a manner similar to the first embodiment, a titanium tungsten (TiW) film having a film thickness of 50 to 200 nm is formed as a barrier metal layer 13 by sputtering. An aluminum strain metal film of a film thickness of 0.3 to 1.0 μm is formed as a wiring layer 12 on the barrier metal layer 13 by sputtering. After that, the reflection preventing film 11 is formed on the aluminum strain metal film by sputtering. The photoresist 10 of the organic substance having a film thickness of 0.5 to 2.5 μm is formed on the reflection preventing film 11 and is patterned to a desired wiring pattern as shown in FIG. 2A.

Further, as shown in FIG. 2B, by performing the etching in a manner similar to the first embodiment, a semiconductor device as shown in FIG. 2C is obtained.

According to the second embodiment, at a time point when the etching of the barrier metal layer 13 is completed in a portion where the wiring pattern is coarse, only an upper portion of the insulating film 20 has been etched. Since an oxygen concentration of the upper portion of the insulating film 20 is small, the emission of oxygen is limited. Therefore, the formation of the side wall protecting film 16 by carbon generated from the organic substance photoresist 10 is not so largely obstructed. The etching progresses in a state in which the side surfaces of the wiring layer 12 under the photoresist 10 are preferably covered by the side wall protecting film 16 as shown in FIG. 2C, so that the occurrence of the side etch as in the conventional technique can be reduced.

As mentioned above, according to the invention, even in case of using an organic substance photoresist as an etching mask for anisotropic etching of the barrier metal layer and the aluminum strain metal film formed on the insulating film into a wiring shape, no side etch occurs in the side wall portion near the interface between the barrier metal layer and the aluminum strain metal film. Thus, a semiconductor device of a good reliability can be provided.

What is claimed is:

1. A semiconductor device comprising:
a semiconductor substrate;
a first insulating film formed on at least a part of said semiconductor substrate and including oxygen as a component;
a second insulating film formed on said first insulating film and substantially including no oxygen as a component;
a first conductive layer selectively formed on said second insulating film; and
a second conductive layer formed on said first conductive layer.

2. A semiconductor device according to claim 1, wherein
said first insulating film includes one selected from a group comprising a BPSG (boro-phospho silicate glass) film, a PSG (phospho-silicate glass) film, a BSG (boro-silicate glass) film, and a plasma silicon oxide (p-SiO) film, and
said second insulating film includes a plasma silicon nitride (p-SiN) film.

3. A semiconductor device comprising:
a semiconductor substrate;
a first insulating film formed on at least a part of said semiconductor substrate and including oxygen as a component;
a second insulating film formed on said first insulating film and having an oxygen concentration smaller than that of said first insulating film;
a first conductive layer selectively formed on said second insulating film; and
a second conductive layer formed on said first conductive layer.

4. A semiconductor device according to claim 3, wherein
said first insulating film includes one selected from a group comprising a BPSG (boro-phospho silicate glass) film, a PSG (phospho-silicate glass) film, a BSG (boro-silicate glass) film, and a plasma silicon oxide (p-SiO) film, and
said second insulating film includes a film made of a mixture of plasma silicon oxide and plasma silicon nitride (p-SiON).

5. A semiconductor device comprising:
a semiconductor substrate;
an insulating film formed on at least a part of said semiconductor substrate and having an oxygen concentration which decreases in accordance with a distance from a surface of said semiconductor substrate;
a first conductive layer selectively formed on said insulating film; and
a second conductive layer formed on said first conductive layer.

6. A semiconductor device according to claim 5, wherein said insulating film includes a film made of a mixture of plasma silicon oxide and plasma silicon nitride (p-SiON).

7. A semiconductor device according to claim 1, wherein
said first conductive layer includes one selected from a group comprising a titanium tungsten (TiW) film, a laminate film of titanium nitride and titanium (TiN/Ti), a tungsten nitride (WN) film, and an alloy film of tungsten and silicon (WSiₓ), and
said second conductive layer includes an aluminum strain metal film.

8. A semiconductor device according to claim 3, wherein
said first conductive layer includes one selected from a group comprising a titanium tungsten (TiW) film, a laminate film of titanium nitride and titanium (TiN/Ti), a tungsten nitride (WN) film, and an alloy film of tungsten and silicon (WSiₓ), and
said second conductive layer includes an aluminum strain metal film.

9. A semiconductor device according to claim 5, wherein
said first conductive layer includes one selected from a group comprising a titanium tungsten (TiW) film, a laminate film of titanium nitride and titanium (TiN/Ti), a tungsten nitride (WN) film, and an alloy film of tungsten and silicon (WSiₓ), and
said second conductive layer includes an aluminum strain metal film.

10. A method for manufacturing a semiconductor device, comprising the steps of:
forming a first insulating film including oxygen as a component on at least a part of a semiconductor substrate;
forming a second insulating film substantially including no oxygen as a component on said first insulating film;
forming a first conductive layer on said second insulating film;
forming a second conductive layer on said first conductive layer; and
patterning said first and second conductive layers by anisotropic etching using an organic substance resist as an etching mask.

11. A method according to claim 10, wherein
said step of forming said first insulating film includes a step of forming one selected from a group comprising a BPSG (boro-phospho silicate glass) film, a PSG (phospho-silicate glass) film, a BSG (boro-silicate glass) film, and a plasma silicon oxide (p-SiO) film, and
said step of forming said second insulating film includes a step of forming a plasma silicon nitride (p-SiN) film.

12. A method for manufacturing a semiconductor device, comprising the steps of:
forming a first insulating film including oxygen as a component on at least a part of a semiconductor substrate;
forming a second insulating film having an oxygen concentration smaller than that of said first insulating film on said first insulating film;
forming a first conductive layer on said second insulating film;
forming a second conductive layer on said first conductive layer; and
patterning said first and second conductive layers by anisotropic etching using an organic substance resist as an etching mask.

13. A method according to claim 12, wherein
said step of forming said first insulating film includes a step of forming one selected from a group comprising a BPSG (boro-phospho silicate glass) film, a PSG (phospho-silicate glass) film, a BSG (boro-silicate glass) film, and a plasma silicon oxide (p-SiO) film, and
said step of forming said second insulating film includes a step of forming a film made of a mixture of plasma silicon oxide and plasma silicon nitride (p-SiON).

14. A method for manufacturing a semiconductor device, comprising the steps of:
forming an insulating film on at least a part of a semiconductor substrate so that an oxygen concentration of said insulating film decreases in accordance with a distance from a surface of said semiconductor substrate;
forming a first conductive layer on said insulating film;
forming a second conductive layer on said first conductive layer; and
patterning said first and second conductive layers by anisotropic etching using an organic substance resist as an etching mask.

15. A method according to claim 14, wherein said step of forming said insulating film includes a step of forming a film made of a mixture of plasma silicon oxide and plasma silicon nitride (p-SiON).

16. A method according to claim 10, wherein
said step of forming said first conductive layer includes a step of forming one selected from a group comprising a titanium tungsten (TiW) film, a laminate film of titanium nitride and titanium (TiN/Ti), a tungsten nitride (WN) film, and an alloy film of tungsten and silicon (WSiₓ), and
said step of forming said second conductive layer includes a step of forming an aluminum strain metal film.

17. A method according to claim 12, wherein
said step of forming said first conductive layer includes a step of forming one selected from a group comprising a titanium tungsten (TiW) film, a laminate film of titanium nitride and titanium (TiN/Ti), a tungsten nitride (WN) film, and an alloy film of tungsten and silicon (WSiₓ), and
said step of forming said second conductive layer includes a step of forming an aluminum strain metal film.

18. A method according to claim 14, wherein said step of forming said first conductive layer includes a step of forming one selected from a group comprising a titanium tungsten (TiW) film, a laminate film of titanium nitride and titanium (TiN/Ti), a tungsten nitride (WN) film, and an alloy film of tungsten and silicon (WSiₓ), and
said step of forming said second conductive layer includes a step of forming an aluminum strain metal film.
